(19) United States
(12) Patent Application Publication
(10) Pub. No.: US 2010/0313926 A1
(43) Pub. Date: Dec. 16, 2010

(54) HEAT-DRIVEN THERMOELECTRIC GENERATOR DEVICE

(75) Inventors: Yu-Ming Sun, Guishan Shiang (TW); Chi-Bin Wu, Guishan Shiang (TW)

Correspondence Address: STITES & HARBISON PLLC, 1199 N. Fairfax Street, Suite 900, Alexandria, VA, 22314, US

(73) Assignee: Chung-Hsin Electric and Machinery Manufacturing Corp., Jhonghe City (TW)

(21) Appl. No.: 12/507,921

(22) Filed: Jul. 23, 2009

(30) Foreign Application Priority Data
Jun. 12, 2009 (TW) 098119793

(51) Int. Cl. H01L 37/00; H01L 35/30

(52) U.S. Cl. 136/206; 136/205

(57) ABSTRACT

A heat-driven thermoelectric generator device is provided. The thermoelectric generator device includes a heat-driven cooling module and a thermoelectric module. The heat-driven cooling module is used to convert heat energy received from outside into cool energy. The thermoelectric module can generate electric power by the temperature difference between the heat energy received from outside and the cool energy generated by the heat-driven cooling module. According to the implementation of the present invention, the thermoelectric generator device can use a natural or artificial heat source as the heat energy to achieve the effect of generating electric power.

### BACKGROUND OF THE INVENTION

1. Technical Field

The present invention relates to heat-driven thermoelectric generator devices and, more particularly, to a heat-driven thermoelectric generator device for use in power generation.

2. Description of Related Art

Electric power is a resource indispensable to our daily life and essential to economic development. There are different kinds of power generation, namely coal-fired power generation, nuclear power generation, etc. However, coal-fired power generation requires coal, petroleum, or liquefied natural gas (LNG) and thus has its own drawbacks, such as over-exploitation of resources and environmental pollution. Likewise, nuclear power generation takes place at the risk of radioactive leak, nuclear waste pollution, etc. Hence, plenty of countries allocate a lot of resources to research on different kinds of renewable energy.

Also, existing power generation devices are composed mostly of various moving parts and therefore have the following disadvantages: they cause environmental pollution, their moving parts produce noise when in operation, and replacement of worn-out moving parts incurs costs.

Thermoelectric cooler (TEC) chips, which used to be applied to aerospace engineering, electric appliances, and so forth, are now used in power generation as well. In the past, electric power was input to thermoelectric cooler chips so as for the thermoelectric cooler chips to provide high-temperature output and low-temperature output. Conversely, it is also feasible for a thermoelectric cooler chip to be coupled to a circuit in order to jointly form a power generation device for generating electric power by the thermoelectric effect and according to variation of a temperature difference. However, as it is difficult to obtain a specific relative temperature difference in practice, power generation with thermoelectric cooler chips by virtue of relative temperature difference is neither effective nor efficient. Accordingly, at present, there is no commercially available power generation devices based on thermoelectric cooler chips.

### SUMMARY OF THE INVENTION

The present invention provides a heat-driven thermoelectric generator device, comprising a heat-driven cooling module for receiving heat energy and converting the heat energy into cool energy so as to enable a marked temperature difference between the heat energy and the cool energy and thereby enable a thermoelectric module to generate electric power by the temperature difference between the heat energy and the cool energy efficiently.

The present invention provides a heat-driven thermoelectric generator device, comprising a heat-driven cooling module for receiving heat energy and converting the heat energy into cool energy so as for a thermoelectric module to receive the heat energy and the cool energy for generating electric power, thereby producing environment-friendly and clean renewable energy.

The present invention provides a heat-driven thermoelectric generator device, wherein a heat-driven cooling module and a thermoelectric module are both free of moving parts such that the heat-driven thermoelectric generator device is advantageously noise-free and has a long service life.

To achieve the above and other effects, the present invention provides a heat-driven thermoelectric generator device, comprising: a heat-driven cooling module for receiving heat energy and converting the heat energy into cool energy; and a thermoelectric module for receiving the heat energy and the cool energy and generating electric power by a temperature difference between the heat energy and the cool energy.

Implementation of the present invention at least involves the following inventive steps:

1. The heat-driven cooling module receives heat energy and converts the heat energy into cool energy so as to enable a marked temperature difference between the heat energy and the cool energy and thereby enable the thermoelectric module to generate electric power efficiently.

2. The heat-driven cooling module works in conjunction with the thermoelectric module to generate electric power and thereby produce environment-friendly and clean renewable energy.

3. With both the heat-driven cooling module and the thermoelectric module being free of moving parts, the heat-driven thermoelectric generator device is advantageously noise-free and has a long service life.

### BRIEF DESCRIPTION OF THE DRAWINGS

The invention as well as a preferred mode of use, further objectives, and advantages thereof will be best understood by reference to the following detailed description of illustrative embodiments when read in conjunction with the accompanying drawings, wherein:

FIG. 1 is a schematic view of a first embodiment of a heat-driven thermoelectric generator device according to the present invention; and

FIG. 2 is a schematic view of a second embodiment of the heat-driven thermoelectric generator device according to the present invention.

### DETAILED DESCRIPTION OF THE PREFERRED EMBODIMENT

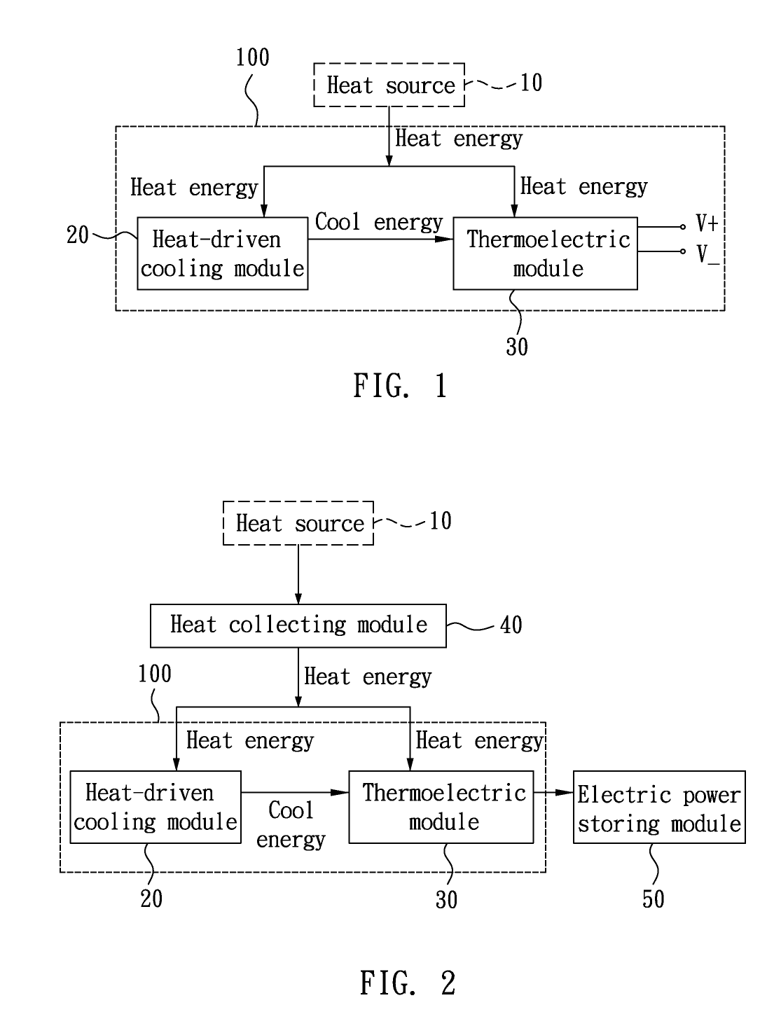

Referring to FIG. 1 and FIG. 2, in preferred embodiments, a heat-driven thermoelectric generator device 100 comprises a heat-driven cooling module 20 and a thermoelectric module 30.

The heat-driven cooling module 20 is generally defined as a device powered by heat energy and configured for energy conversion that entails taking in heat energy and converting the heat energy into cool energy. The heat energy that the heat-driven cooling module 20 needs in order to work originates from a natural heat source 10 or an artificial heat source 10, such as solar heat energy, geothermal energy, combustion heat energy, heat generated by chemical reactions, waste heat from a cogeneration system, industrial waste heat, or waste heat from vehicles.

The heat-driven cooling module 20 is an adsorptive cooling module or a liquid absorptive cooling module. The adsorptive cooling module is a solid adsorptive cooling module.

The adsorptive cooling module, which works under the principles of adsorptive refrigeration, cools and heats an adsorbent (also known as an adsorbing agent) periodically by making good use of the adsorptive characteristic of the adsorbent toward a refrigerant (such as a coolant), so as to enable the adsorbent to effect adsorption and desorption alternately.

For instance, the adsorbent when at low temperature can adsorb plenty of coolant vapor, and thus refrigeration occurs whenever the coolant evaporates (i.e., when the liquid coolant is turned into coolant vapor). Once the adsorbent takes in heat energy and is thus heated up, the coolant vapor is desorbed from the saturated adsorbent so as for the coolant to condense (i.e., undergo transition from a gaseous state to a liquid state). Hence, the adsorptive cooling module can be implemented by an evaporator and a condenser, or simply an evaporation-condensation apparatus, where the adsorbent and the coolant together effect adsorption and desorption interactively. The adsorbent and the coolant are periodically cooled and heated so as to receive heat energy and convert the heat energy into cool energy.

Only in the interactive presence of an adsorbent and a coolant can refrigeration be efficiently provided by the adsorptive cooling module. Since the adsorptive cooling module cannot work without a medium, that is, the adsorbent and the coolant to be adsorbed by and desorbed from the adsorbent, it is necessary that the adsorbent match the coolant so as for the adsorptive cooling module to provide efficient refrigeration. For instance, a combination of silica gel functioning as the adsorbent and water as the coolant, a combination of zeolite as the adsorbent and water as the coolant, or a combination of activated carbon as the adsorbent and methanol or ethanol as the coolant is a good match. By a similar principle, a liquid absorptive cooling module operates in conjunction with an adsorbent and a coolant, wherein, for example, a combination of lithium bromide functioning as the adsorbent and water as the coolant or a combination of water functioning as the adsorbent and ammonia as the coolant is a good match.

The thermoelectric module 30 is generally defined as a module fabricated by the principles of thermoelectricity, such as a thermoelectric cooler chip or a module characterized by the thermoelectric effect and made of diodes. The thermoelectric module 30 comprises a heat energy receiving end, a cool energy receiving end, and an electric power outputting end. The heat energy receiving end of the thermoelectric module 30 receives heat energy from the natural heat source 10 or the artificial heat source 10 while the cool energy receiving end of the thermoelectric module 30 receives cool energy generated by the heat-driven cooling module 20. Thus, electric power is generated by a temperature difference between the heat energy and the cool energy. The electric power is output upon electrical connection between the electric power outputting end and an external circuit.

As mentioned earlier, the heat-driven cooling module 20 receives heat energy from the natural heat source 10 or the artificial heat source 10 and converts the heat energy into cool energy such that there is a marked temperature difference between the heat energy received by the heat-driven cooling module 20 and the cool energy generated by the heat-driven cooling module 20. Hence, the heat-driven cooling module 20 is fit for use with the thermoelectric module 30 and for enhancing the performance of the thermoelectric module 30 in power generation.

Referring to FIG. 2, to allow heat energy that originates from the natural heat source 10 or the artificial heat source 10 to be effectively collected, a heat collecting module 40 is provided for collecting heat energy. Besides, the electric power outputting end of the thermoelectric module 30 is electrically connected to an electric power storing module 50 so as for electric power generated by the thermoelectric module 30 to be effectively stored in the electric power storing module 50 for later use.

Since the temperature difference between the heat energy received by the heat-driven cooling module 20 and the cool energy generated by the heat-driven cooling module 20 through energy conversion is great, the thermoelectric module 30 makes effective use of the heat energy received and the cool energy generated by the heat-driven cooling module 20 to generate electric power. Also, with the heat energy being solar heat energy, geothermal energy, combustion heat energy, heat generated by chemical reactions, waste heat from a cogeneration system, industrial waste heat, or waste heat from vehicles, electric power generated by the thermoelectric generator device 100 is environment-friendly and clean renewable energy. Furthermore, with the thermoelectric generator device 100 being free of moving parts, the thermoelectric generator device 100 is advantageously noise-free and has a long service life.

The foregoing embodiments are illustrated only to disclose the technical features of the present invention so as to enable a person skilled in the art to understand such features and implement the present invention accordingly. It is understood that the embodiments are not restrictive of the scope of the present invention. Hence, all equivalent modifications and variations made to the foregoing embodiments without departing from the spirit and principles of the disclosure of the present invention should fall within the scope of the appended claims.

What is claimed is:

1. A heat-driven thermoelectric generator device, comprising:
a heat-driven cooling module for receiving heat energy and converting the heat energy into cool energy; and
a thermoelectric module for receiving the heat energy and the cool energy and generating electric power by a temperature difference between the heat energy and the cool energy.

2. The heat-driven thermoelectric generator device of claim 1, wherein the heat energy originates from a natural heat source or an artificial heat source.

3. The heat-driven thermoelectric generator device of claim 1, wherein the heat energy is solar heat energy, geothermal energy, combustion heat energy, heat generated by chemical reactions, waste heat from a cogeneration system, industrial waste heat, or waste heat from vehicles.

4. The heat-driven thermoelectric generator device of claim 1, wherein the heat-driven cooling module is an adsorptive cooling module.

5. The heat-driven thermoelectric generator device of claim 4, wherein the adsorptive cooling module is a solid adsorptive cooling module.

6. The heat-driven thermoelectric generator device of claim 4, wherein the adsorptive cooling module comprises an adsorbent provided in form of silica gel and a coolant provided in form of water.

7. The heat-driven thermoelectric generator device of claim 4, wherein the adsorptive cooling module comprises an adsorbent provided in form of zeolite and a coolant provided in form of water.

8. The heat-driven thermoelectric generator device of claim 4, wherein the adsorptive cooling module comprises an adsorbent provided in form of activated carbon and a coolant provided in form of methanol.

9. The heat-driven thermoelectric generator device of claim 4, wherein the adsorptive cooling module comprises an adsorbent provided in form of activated carbon and a coolant provided in form of ethanol.

10. The heat-driven thermoelectric generator device of claim 1, wherein the heat-driven cooling module is a liquid absorptive cooling module.

11. The heat-driven thermoelectric generator device of claim 10, wherein the liquid absorptive cooling module comprises an adsorbent provided in form of lithium bromide and a coolant provided in form of water.

12. The heat-driven thermoelectric generator device of claim 10, wherein the liquid absorptive cooling module comprises an adsorbent provided in form of water and a coolant provided in form of ammonia.

13. The heat-driven thermoelectric generator device of claim 1, wherein the thermoelectric module is a thermoelectric cooler (TEC) chip.

14. The heat-driven thermoelectric generator device of claim 1, wherein the thermoelectric module is a module characterized by thermoelectric effect and made of diodes.
